(19) United States
(12) Patent Application Publication
(10) Pub. No.: US 2026/0288184 A1
(43) Pub. Date: Sep. 24, 2026

(54) LOW DROPOUT (LDO) REGULATOR DEVICE AND METHOD THEREOF

(71) Applicants: SAMSUNG ELECTRONICS CO., LTD., Suwon-si (KR); SAMSUNG ELECTRONICS CO., LTD., Suwon-si (KR)

(72) Inventors: Anirban Barman, Bengaluru (IN); Deepa Devendran, Bengaluru (IN)

(21) Appl. No.: 19/551,154

(22) Filed: Feb. 26, 2026

(30) Foreign Application Priority Data
Mar. 22, 2025 (IN) 202541026356
Sep. 18, 2025 (IN) 202541026356

(51) Int. Cl. G05F 1/575; H03K 19/0185

(52) U.S. Cl. CPC G05F 1/575; H03K 19/018507

(57) ABSTRACT

A Low Dropout (LDO) regulator device is provided. The LDO regulator device includes an amplifier that provides at least one of a linear output voltage and a feedback voltage, the linear output voltage indicating an error signal from a reference voltage, a current mirror-based level shifter coupled with the amplifier, the current mirror-based level shifter configured to provide a stable reference current based on at least one of the linear output voltage and the feedback voltage, and a power Metal Oxide Semiconductor Field Effect Transistor (MOSFET) module including a first N-channel MOSFET (NMOS) transistor configured to provide a sourcing power supply to a load and a second NMOS transistor configured to provide a sinking power supply to the load. The first NMOS transistor is coupled to the amplifier via the current mirror-based level shifter, and the second NMOS transistor is coupled to the amplifier.

### CROSS-REFERENCE TO RELATED APPLICATIONS

This application is based on and claims priority from Indian Patent Application number 202541026356 filed on Sep. 18, 2025, and Indian Provisional Patent Application No. 202541026356, filed on Mar. 22, 2025, in the Indian Patent Office, the disclosure of which is incorporated herein by reference in its entirety.

### BACKGROUND

### 1. Field

The disclosure relates to the field of driver circuitry devices and more particularly relates to a Low Dropout (LDO) regulator device and method for providing sourcing power supply and sinking power supply to a load.

### 2. Description of Related Art

A Low Dropout (LDO) regulator operates with a very small difference (or dropout voltage) between input and output voltages, typically in the range of 0.1V to 2V depending on a design of the LDO regulator. In general, the LDO regulators maintain a stable and regulated output voltage, even when an input voltage fluctuates within a specific range. The LDO regulators operate in a linear mode, making the LDO regulators suitable for applications requiring low noise and precise voltage regulation. The LDO regulators primarily have to source current capability to provide power to a load. The LDO regulator includes a Class-AB amplifier used to support sourcing and sinking currents to improve functionality.

However, in related art class-AB LDO regulators, a P-type Metal-Oxide-Semiconductor (PMOS) transistor for sourcing current and an N-type Metal-Oxide-Semiconductor (NMOS) transistor for sinking current power transistors are utilized. The class-AB LDO regulators may have certain limitations such as the PMOS transistor dominates a design area, and as load current increases, the PMOS transistor area grows significantly, leading to increased circuit size.

Meanwhile, the N-type transistor is preferred for low-area designs. However, related art class-AB LDO regulators do not support the N-type transistor for the sourcing and sinking currents. Thus, achieving an efficient and compact LDO regulator with sourcing and sinking capabilities remains challenging. The current class-AB LDO regulators create the need for a novel class-AB LDO regulator that uses N-type pass devices for sourcing and sinking currents to reduce area and optimize performance in the LDO regulator operating in converter output domains.

FIG. 1 illustrates an exemplary architecture of a related art LDO regulator 100. As depicted in FIG. 1, the LDO regulator 100 includes an error amplifier 102, a source follower 104, and a power Metal Oxide Semiconductor Field Effect Transistor (MOSFET) 106. The error amplifier 102 is typically used to compare a feedback voltage with a reference voltage and generate an error signal. The error signal serves as a control input to adjust the output of the LDO regulator 100 to match the desired reference voltage. Further, the source follower 104 may be in conjunction with the error amplifier 102 to provide a low-impedance output while maintaining voltage stability. In the LDO regulator 100, the source follower 104 may enhance stability and improve the LDO regulator's response to dynamic load changes.

The LDO regulator 100 operates using a voltage provided by an External Low Voltage Drain Domain (ELVDD). The ELVDD refers to a voltage level generated by a converter. The converter may step down a higher input voltage to a lower level suitable for the operation of the LDO regulator 100. In the LDO regulator 100, the PMOS transistor is utilized for sourcing current, while the NMOS transistor handles sinking current. Notably, as the load current increases, the area of the PMOS transistor also increases proportionally, enabling the PMOS transistor to accommodate the higher current demands efficiently.

The LDO regulator 100, as shown in FIG. 1, demonstrates some limitations when it comes to sourcing and sinking current efficiently. The LDO regulator 100 predominantly relies on the PMOS transistor for sourcing current. The NMOS transistor is used to handle the sinking current. However, as the load current increases, the area of the PMOS transistor must also increase to handle higher current demands effectively, which can result in increased area and reduced efficiency.

The LDO regulator 100 presents a technical problem in achieving compactness and efficiency in the LDO regulator. The increase in PMOS transistor area leads to a less optimal solution, especially in applications where the sourcing and sinking currents are required. The LDO regulator 100 creates a challenge for improving performance, specifically in terms of the ability to support higher currents without unnecessary area expansion. A novel approach is needed to address the limitations by introducing an improved LDO regulator capable of efficiently handling the sourcing and sinking currents without the increased area.

### SUMMARY

According to an aspect of the disclosure, there is provided a Low Dropout (LDO) regulator device including: an amplifier configured to provide at least one of a linear output voltage and a feedback voltage, the linear output voltage indicating an error signal from a reference voltage; a current mirror-based level shifter coupled with the amplifier, the current mirror-based level shifter configured to provide a stable reference current based on at least one of the linear output voltage and the feedback voltage; and a power Metal Oxide Semiconductor Field Effect Transistor (MOSFET) module including a first N-channel MOSFET (NMOS) transistor configured to provide a sourcing power supply to a load and a second NMOS transistor configured to provide a sinking power supply to the load, wherein the first NMOS transistor is coupled to the amplifier via the current mirror-based level shifter, and the second NMOS transistor is coupled to the amplifier.

According to another aspect of the disclosure, there is provided a method for providing a sourcing power supply and a sinking power supply to a load, the method including: generating, by an amplifier, at least one of a linear output voltage and a feedback voltage, the linear output voltage indicating an error signal derived from a reference voltage; performing, by the amplifier, at least one of: increasing a control voltage of a first NMOS device to enable the sourcing power supply to the load based on the linear output voltage; increasing a control voltage of a second NMOS device to enable the sinking power supply to the load based on the linear output voltage; and regulating an output voltage of the LDO regulator device to provide the sourcing power supply and the sinking power supply to the load.

To further clarify the advantages and features of the disclosure, a more detailed description of the disclosure will be rendered by reference to specific examples thereof, which are illustrated in the appended drawings. It is appreciated that these drawings depict only typical examples of the disclosure and are therefore not to be considered limiting its scope. The disclosure will be described and explained with additional specificity and detail with the accompanying drawings.

### BRIEF DESCRIPTION OF DRAWINGS

Example implementations will be more clearly understood from the following detailed description, taken in conjunction with the accompanying drawings.

FIG. 1 illustrates an exemplary architecture of a Low Dropout (LDO) regulator in accordance with related art;

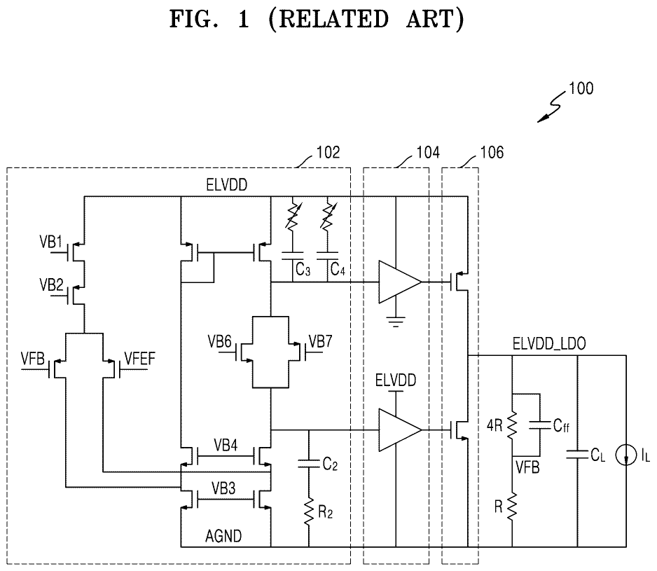

FIG. 2 illustrates a schematic block diagram of a Low Dropout (LDO) regulator device for providing a sourcing power supply and a sinking power supply to a load, in accordance with embodiments of the disclosure; and

FIG. 3 illustrates a flowchart depicting a method for regulating voltage in the LDO regulator device, in accordance with an embodiment of the disclosure.

Further, skilled artisans will appreciate those elements in the drawings are illustrated for simplicity and may not have necessarily been drawn to scale. For example, the flow charts illustrate the method in terms of the most prominent operations involved to help to improve understanding of aspects of the disclosure. Furthermore, in terms of the construction of the device, one or more components of the device may have been represented in the drawings by conventional symbols, and the drawings may show only those specific details that are pertinent to understand embodiments of the disclosure so as not to obscure the drawings with details that will be readily apparent to those of ordinary skill in the art having the benefit of the description herein.

### DETAILED DESCRIPTION

For the purpose of promoting an understanding of the principles of the disclosure, reference will now be made to embodiments and specific language will be used to describe the same. It will nevertheless be understood that no limitation of the scope of the disclosure is thereby intended, such alterations and further modifications in the illustrated system, and such further applications of the principles of the disclosure as illustrated therein being contemplated as would normally occur to one skilled in the art to which the disclosure relates.

The term “some” or “one or more” as used herein is defined as “one”, “more than one”, or “all.” Accordingly, the terms “more than one,” “one or more” or “all” would all fall under the definition of “some” or “one or more”. The term “an embodiment”, “another embodiment”, “some embodiments”, “embodiments” or “in one or more embodiments” may refer to one embodiment or several embodiments, or all embodiments. Accordingly, the terms “some embodiments” and “embodiments” are defined as meaning “one embodiment, or more than one embodiment, or all embodiments”.

The terminology and structure employed herein are for describing, teaching, and illuminating embodiments and their specific features and elements and do not limit, restrict, or reduce the spirit and scope of the claims or their equivalents. The phrase “exemplary” may refer to an example.

More specifically, any terms used herein such as but not limited to “includes,” “comprises,” “has,” “include”, “comprising”, “have”, and grammatical variants thereof do not exclude the possible addition of one or more features or elements, unless otherwise stated, and must not be taken to exclude the possible removal of one or more of the listed features and elements, unless otherwise stated, for example, with the limiting language “must comprise” or “needs to include”.

Whether or not a certain feature or element was limited to being used only once, either way, it may still be referred to as “one or more features”, “one or more elements”, “at least one feature”, or “at least one element”. Furthermore, the use of the terms “one or more” or “at least one” feature or element does not preclude there being none of that feature or element unless otherwise specified by limiting language such as “there needs to be one or more” or “one or more element is required.”

Unless otherwise defined, all terms, and especially any technical and/or scientific terms, used herein may be taken to have the same meaning as, or a similar meaning to, that commonly understood by one having ordinary skill in the art.

In the disclosure, implementations may be described and illustrated in terms of blocks that carry out a described function or functions. These blocks, which may be referred to herein as units or circuits or modules or the like, may be physically implemented by analog or digital circuits such as logic gates, integrated circuits, microprocessors, microcontrollers, memory circuits, passive electronic components, active electronic components, optical components, hardwired circuits, or the like, and may optionally be driven by firmware and software. The circuits may, for example, be implemented in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the implementations may be physically separated into two or more interacting and discrete blocks without departing from the scope of the disclosure. Likewise, the blocks of the implementations may be physically combined into more complex blocks without departing from the scope of the disclosure.

Embodiments of the disclosure will be described below in detail with reference to the accompanying drawings.

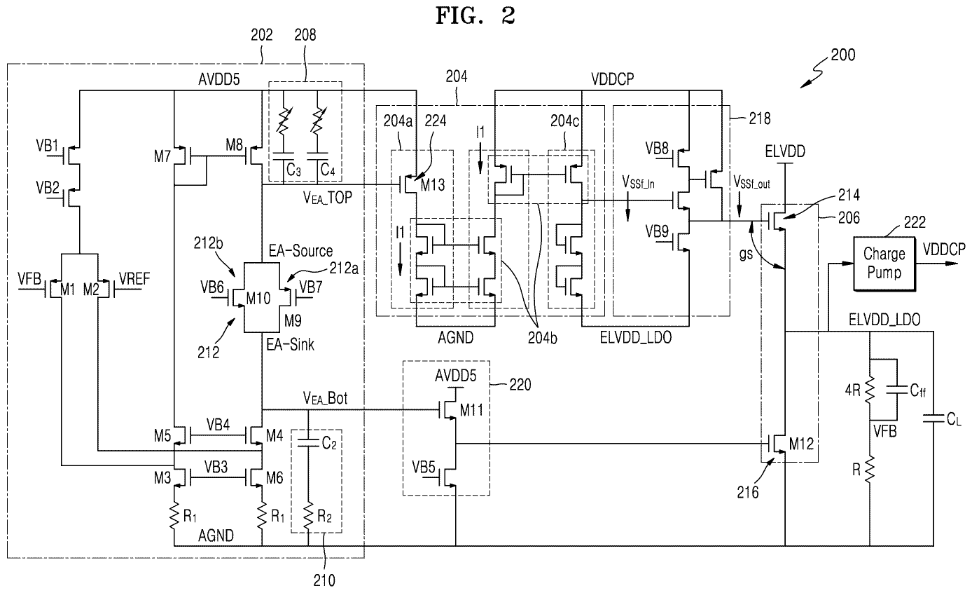

FIG. 2 illustrates a schematic circuit diagram of a Low Dropout (LDO) regulator device 200 for providing a sourcing power supply and a sinking power supply to a load, in accordance with embodiments of the disclosure. The LDO regulator device 200 may include an error amplifier 202, a current mirror-based level shifter 204, and a power Metal Oxide Semiconductor Field Effect Transistor (MOSFET) module 206. The power MOSFET module 206 may include a first NMOS device 214 and a second NMOS device 216. For example, the first NMOS device 214 may be an NMOS transistor and the second NMOS device 216 may be an NMOS transistor. The power MOSFET module 206 may be responsible for sourcing and sinking currents in the LDO regulator device 200. The first NMOS device 214 and the second NMOS device 216 may be controlled by the error amplifier 202 and the current mirror-based level shifter 204.

In an embodiment, the error amplifier 202 may be configured to provide a linear output voltage and a feedback voltage. For example, the error amplifier may be a class AB error amplifier 202 as described hereafter according to an example embodiment. However, the disclosure is not limited thereto. The linear output voltage may indicate an error signal from a reference voltage. The error signal may be an output signal generated by the class AB error amplifier 202 based on a comparison between the feedback voltage (VFB) from the load and the reference voltage (VREF). For example, the error signal may represent the difference between the feedback voltage and the reference voltage. The feedback voltage may be a signal used to maintain stability of the LDO regulator device 200 by regulating the linear output voltage. The feedback voltage may be configured to enable the class AB error amplifier 202 to determine whether the linear output voltage is above, below, or at a desired level.

The error signal may be transmitted through the current mirror-based level shifter 204 to bias a gate of the first NMOS device 214 and a gate of the second NMOS device 216. The current mirror-based level shifter 204 may be a circuit that performs the function of translating a signal from one voltage domain to another. The current mirror-based level shifter 204 may include a voltage-to-current converter 204a, a current mirror 204b, and a current-to-voltage converter 204c.

For example, the current mirror-based level shifter 204 may level shift an output voltage signal of the class AB error amplifier 202 from a low-voltage domain of the LDO regulator 200 (e.g., 5V) to a higher voltage domain (e.g., the sum of the LDO output voltage and 5V). The current mirror-based level shifter 204 may be configured to enable control signals to drive the first NMOS device 214 and the second NMOS device 216. The voltage-to-current converter 204a may be configured to convert the output voltage signal from the class AB error amplifier 202 into a corresponding current signal (e.g., V_{EA}_TOP to I₁) in a low voltage domain of the LDO regulator 200 (e.g., 5V). The current mirror 204b may change the corresponding current signal from the low-voltage domain of the LDO regulator 200 (e.g., 5V) to a higher voltage domain (e.g., the sum of the LDO output voltage and 5V). The current-to-voltage converter 204c may convert a replicated current signal into a voltage signal (e.g., I₁ to V_{SSf_In}) in the higher voltage domain (e.g., the sum of the LDO output voltage and 5V).

The current mirror-based level shifter 204 may be configured to provide the stable reference voltage in the low voltage domain of the LDO regulator 200 based on at least one of the linear output voltage from the class AB error amplifier 202 and the feedback voltage. The stable reference voltage may indicate a constant and precise voltage generated by the current mirror-based level shifter 204 to ensure reliable operation of the LDO regulator 200 under varying load and input conditions. The stable reference voltage may drive or bias gate terminals of the first NMOS device 214 and the second NMOS device 216.

The first NMOS device 214 may be coupled to the class AB error amplifier 202 via the current mirror-based level shifter 204. The first NMOS device 214 may be configured to provide the sourcing power supply to the load. The second NMOS device 216 may be coupled to the class AB error amplifier 202. The second NMOS device 216 may be configured to provide the sinking power supply to the load.

The class AB error amplifier 202 may be configured to compare the feedback voltage with the reference voltage. In an embodiment, the class AB error amplifier 202 may be operated in analog voltage domain, for example, in the 5V (AVDD5) domain. The class AB error amplifier 202 may be configured to increase or decrease the linear output voltage based on the output of the load. In an example case in which the load requires more current, the first NMOS device 214 adjusts a gate voltage to increase a sourcing current while maintaining a stable linear output voltage. In an example case in which the load requires a sinking current, the second NMOS device 216 adjusts the gate voltage to facilitate the sinking current while maintaining the stable linear output voltage.

The class AB error amplifier 202 may include a source current compensation component 208, a sink current compensation component 210, and a biasing component 212. According to an embodiment, the components illustrated in FIG. 2 may also be referred to as circuits. The source current compensation component 208 and the sink current compensation component 210 may be configured to manage the sourcing and sinking of current through the power MOSFET module 206 in the LDO regulator device 200. The LDO regulator device 200 may include at least one PMOS transistor 224 configured to act as a passive power transistor. The current information of the PMOS transistor 224 may be processed and used to bias the first NMOS device 214. For example, the first NMOS device 214 may be biased based on a current across the PMOS transistor 224. The LDO regulator device 200 may include a plurality of transistors including, but not limited to transistors M1, M2, M3, M4, M5, M6, M7, M8, M9, and M10. For example, the transistors M1, M2, M3, M4, M5, M6, M7, M8, M9, and M10 may include, but are not limited to, MOSFETs, and the like.

The biasing component 212 may include at least one PMOS transistor 212a and at least one NMOS transistor 212b. The at least one PMOS transistor 212a and at least one NMOS transistor 212b may be biased at zero load condition. The biasing component 212 may generate the gate voltage for the first NMOS device 214 and the second NMOS device 216. In an example case in which the sourcing load increases, the linear output voltage decreases, which results in a reduction in the feedback voltage. Accordingly, the error signal at the input of the class AB error amplifier 202 increases in the positive direction, as represented by the relationship mentioned in equation (1):

$$VREF = VFB + VΔV\_ \{ REF \} = V\_ \{ FB \} + V\_ \{ ∖ Delta \} VREF = VFB + V Δ \qquad ( 1 )$$

Here, VREF may indicate the reference voltage, VFB may indicate the feedback voltage, REF may indicate the reference voltage, VAV may indicate a difference between the reference voltage (VREF), and the feedback voltage (VFB).

According to an embodiment, a positive error signal may cause the output signal of the class AB error amplifier 202 to decrease. The positive error signal may indicate a signal generated by the class AB error amplifier 202 in an example case in which the feedback voltage is lower than the reference voltage. According to an embodiment, based on or in response to the positive error signal, the biasing component 212 may adjust by increasing the gate-to-source voltage (VGSV_{GS}VGS) of a top-side power MOSFET module 206, enabling the biasing component 212 to provide more sourcing power supply. In an example case in which the sinking load increases, the linear output voltage increases, leading to an increase in the feedback voltage. The error signal at the input of the class AB error amplifier 202 increases in the negative direction, as represented by the relationship mentioned in equation (2):

$$VREF = VFB - VΔV\_ \{ REF \} = V\_ \{ FB \} - V\_ \{ ∖ Delta \} VREF = VFB - V Δ \qquad ( 2 )$$

According to an embodiment, a negative error signal may cause the output signal of the class AB error amplifier 202 to increase. According to an embodiment, based on or in response to the negative error signal, the biasing component 212 may adjust by increasing the VGSV_{GS}VGS of the bottom-side power MOSFET module 206, enabling it to provide the sinking current.

According to an embodiment, a bias voltage VB6 of transistor M10 and a bias voltage VB7 of transistor M9 may be as mentioned in equation (3):

$${VB}_{6} = {Vgs}_{10} + {Vgs}_{11} + {Vgs}_{12} , {VB}_{7} = AVDD 5 - ( {Vgs}_{9} + {Vgs}_{13} ) \qquad ( 3 )$$

For example, the bias voltage VB6 may be determined by a sum of the gate-to-source voltages (VgsV_{GS}Vgs) of three transistors M10, M11, M12 as follows:
Vgs10V_{GS10}Vgs10: The gate-to-source voltage of transistor M10
Vgs11V_{GS11}Vgs11: The gate-to-source voltage of transistor M11
Vgs12V_{GS12}Vgs12: The gate-to-source voltage of transistor M12

For example, the bias voltage VB7 may be defined by subtraction of the gate-to-source voltages (VGS9V_{GS9}VGS9 and VGS13V_{GS13} VGS13) of transistors M9 and M13 from applied supply voltage AVDD5. The applied supply voltage AVDD5 may include a power supply voltage domain, typically 5V or another specified value.

According to an embodiment, the applied supply voltage AVDD5 may establish the required operating condition for transistors M9 and M13.

The bias voltage may be determined by sum of gate-to-source voltages. The voltages VB5 and VB6 may be fixed bias voltages configured to ensure that the current flowing through the transistors M9 and M10 is half of the current flowing through the transistor M8 at no load condition.

According to an embodiment, an error amplifier source (EA_SOURCE) node may be configured to decrease based on or in response to an increase in the sourcing power supply for the first NMOS device 214. As the EA SOURCE node voltage decreases, the gate-to-source voltage (VGS) of the transistor M9 reduces, causing a decrease in the current through the transistor M9. Thus, the current may be increased through the transistor M10. The increase in current through the transistor M10 requires an error amplifier sink (EA_SINK) node to decrease, reducing the sinking power supply provided by the second NMOS device 216.

Similarly, the EA_SINK node is configured to increase based on or in response to an increase in the sinking load current for the second NMOS device 216. As the EA SINK node voltage increases, the gate-to-source voltage (VGS) of transistor M10 decreases, reducing the current through the transistor M10. This reduction causes an increase in the current through the transistor M9. As a result, the EA_SOURCE node voltage increases, which reduces the source current provided by the first NMOS device 214. The dynamic adjustment of EA_SOURCE and EA_SINK may ensure stable operation by balancing the sourcing power supply and the sinking power supply to regulate the load effectively.

The source current compensation component 208 may be configured to regulate the sourcing current provided by the first NMOS device 214. The sink current compensation component 210 may be configured to regulate the sinking current absorbed by the second NMOS device 216 to stabilize the linear output voltage. The biasing component 212 may be configured to adjust a control voltage for the first NMOS device 214 and the second NMOS device 216 based on the linear output voltage.

According to an embodiment, a super source follower component 218 may be coupled with the class AB error amplifier 202 via the current mirror-based level shifter 204 and the first NMOS device 214. An input of the super source follower component 218 may represent a control signal derived from the feedback voltage and the reference voltage processed by the class AB error amplifier 202. The input of the super source follower component 218 may control the operation of the super source follower component 218, enabling the super source follower component 218 to adjust the voltage applied to the gate of the first NMOS device 214.

The source current compensation component 208 may be configured to stabilize the LDO regulator device 200 for the source current range. For example, the source current compensation component 208 may add multiple poles and zeros at a source node (EA_SOURCE node) of the class AB error amplifier 202 in order to produce good phase margin and gain margin. For example, a phase margin and/or a gain margin satisfying a predetermined criteria may be produced. The super source follower component 218 may be configured to receive a level-shifted output signal from the current mirror-based level shifter 204. The level-shifted output signal may refer to the voltage signal generated by the current mirror-based level shifter 204 that has been shifted from one voltage domain to another. For example, the current mirror-based level shifter 204 translates the output signal from the voltage domain (e.g., 5V) of the class AB error amplifier 202 to the operating voltage domain of the LDO regulator device 200 (e.g., LDO Output+5V).

The super source follower component 218 may be configured to provide a low output impedance to drive a gate of the first NMOS device 214. The low output impedance of the super source follower component 218 may indicate efficiently driving the gate of the first NMOS device 214 without significant voltage drop or signal loss. The output impedance may indicate resistance or impedance presented by the output node of the super source follower component 218. The low output impedance may ensure that the gate of the first NMOS device 214 is charged or discharged quickly. For example, by the gate of the first NMOS device 214 being charged or discharged quickly, it may be possible to efficiently and/or accurately respond to changes in the load and maintain voltage regulation.

The super source follower component 218 may include at least one PMOS transistor and at least one NMOS transistor. The first NMOS device 214 may be used as a common drain configuration and the PMOS transistor is connected to an output node of the super source follower component 218.

A source follower component 220 may be coupled with the class AB error amplifier 202 and the second NMOS device 216. The sink current compensation component 210 may be configured to stabilize the LDO regulator device 200 for a sink current range. For example, the sink current compensation component 210 may add one or more poles and zeroes at the error amplifier sink node (EA-sink) in order to produce good phrase margin and gain margin. For example, a phase margin and/or a gain margin satisfying a predetermined criteria may be produced. The source follower component 220 may be configured to buffer the linear output voltage of the class AB error amplifier 202. Further, the source follower component 220 may be configured to provide the low output impedance to drive the gate of the second NMOS device 216.

The source follower component 220 may be a common-drain amplifier. The source follower component 220 may include a first NMOS transistor configured to use as a common drain and a second NMOS transistor configured to bias the source follower component 220. The second NMOS device 216 may be connected to an output node of the source follower component 220. A charge pump 222 may be configured to generate a biasing voltage. The biasing voltage may be applied to the first NMOS device 214. For example, the charge pump 222 generates 5 volts plus the output voltage of the LDO regulator device 200. The charge pump 222 may be a circuit element used to generate higher or lower voltage levels than the applied supply voltage to facilitate the efficient operation of the LDO regulator device 200. The charge pump 222 may be configured to provide a voltage level required for driving the gate of the first NMOS device 214.

The LDO regulator device 200 may be configured to exhibit stable and reliable performance, even under fluctuating load and line conditions. For example, at a maximum load of 1.6 Amps, a Power Supply Rejection Ratio (PSRR) is −30 decibels (dB), while at a lighter load of 200 mA, the PSRR improves to −40 dB. The LDO regulator device 200 may exhibit a fast load transient response, capable of handling a load variation of 100 mA within 300 microseconds, with an output peak-to-peak ripple of less than 1 mV.

The load regulation of the LDO regulator device 200 may be highly stable, with an output variation of only 3 mV across a load range from −100 mA to 1.6 A. During line transients, where the input voltage varies between 5.5V and 22V with a slope of 20 mV/us, the LDO regulator device 200 may maintain an output peak-to-peak ripple of less than 5m V. Furthermore, the LDO regulator device 200 may provide output noise measured at less than 100 microvolts root mean square (μVrms) over a frequency range of 100 Hz to 1 MHz, ensuring a clean and stable output for sensitive applications.

For example, the sensitive applications may include, but are not limited to, electronic systems or devices, high-speed communication systems, analog circuits, medical devices, audio equipment, advanced microprocessors, and the like. The sensitive applications may require precise voltage regulation with minimal noise, high PSRR, and stable operation under varying load and line conditions. The sensitive applications may be highly sensitive to fluctuations in supply voltage, transient responses, and noise.

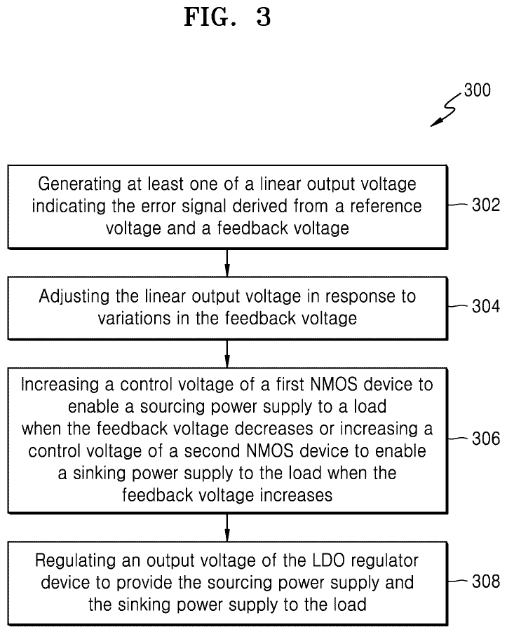

FIG. 3 illustrates a flowchart 300 depicting a method for regulating voltage in the LDO regulator device 200, in accordance with an embodiment of the disclosure.

According to an embodiment, in operation 302, the method 300 may include generating at least one of the linear output voltage and the feedback voltage. For example, the class AB error amplifier 202 may be configured to generate at least one of the linear output voltage and the feedback voltage. For example, the linear output voltage may correspond to or indicate the error signal derived from the reference voltage.

According to an embodiment, in operation 304, the method 300 may include adjusting the linear output voltage based on variations in the feedback voltage. For example, the class AB error amplifier 202 may be configured to adjust the linear output voltage based on or in response to variations in the feedback voltage.

According to an embodiment, in operation 306, the method 300 may include performing at least one of: increasing a control voltage of the first NMOS device 214 to enable the sourcing power supply to the load based on the generated linear output voltage or increasing a control voltage of a second NMOS device to enable a sinking power supply to the load based on the generated linear output voltage. For example, the class AB error amplifier 202 may be configured to increase a control voltage of the first NMOS device 214 to enable the sourcing power supply to the load based on the generated linear output voltage or increase a control voltage of a second NMOS device to enable the sinking power supply to the load based on the generated linear output voltage.

According to an embodiment, in operation 308, the method 300 may include regulating the output voltage of the LDO regulator device 200 to provide the sourcing power supply and the sinking power supply to the load.

One or more embodiments of the disclosure may provide various technical advancements based on the one or more features discussed above. According to one or more embodiments of the disclosure, there is provided an internal charge pump that enables efficient power management, reducing the need for external components and saving valuable silicon area. One or more embodiments of the disclosure may provide features that are advantageous for current and future N-channel Low Dropout (N-LDO) designs, paving the way for more compact and cost-effective implementations. One or more embodiments of the disclosure may provide implementations to effectively stabilize class AB amplifier compensation across a wide range of load currents, overcoming the challenges typically associated with related art designs. Unlike class A amplifier architecture with auxiliary loops, which lack robust load regulation, the class AB amplifier approach ensures precise and consistent voltage regulation over varying load conditions.

One or more embodiments of the disclosure may effectively balance sourcing and sinking currents, maintaining optimal performance even under demanding load transitions. The balanced sourcing and sinking currents result in reduced output voltage deviations and better overall reliability.

One or more embodiments of the disclosure may provide a class AB error amplifier configured to generate the linear output voltage based on the difference between the reference voltage and the feedback voltage. The error signal controls the gate voltages of the first NMOS device and the second NMOS device without fail. In an example, case in which the load demands more current (e.g., the load requires an increase in current), the class AB error amplifier increases the control voltage of the first NMOS device, allowing the first NMOS device to supply additional current. Conversely, during negative transients, the class AB error amplifier reduces the control voltage of the second NMOS device to sink excess current from the load. The feedback loop continuously adjusts the error signal to maintain the linear output voltage at the desired level, regardless of variations in the load or input voltage.

One or more embodiments of the disclosure may stabilize the class AB wide load range LDO by leveraging innovative compensation techniques. One or more embodiments of the disclosure may ensure consistent operation from low to high current loads, making the LDO regulator device suitable for a variety of power-intensive applications.

One or more embodiments of the disclosure may include advanced compensation and control schemes to minimize output noise and ripple, ensuring compatibility with noise-sensitive applications such as analog and RF circuits. The charge pump eliminates the additional power supply, allowing the LDO to operate efficiently across various input-output voltage scenarios. One or more embodiments of the disclosure may provide a robust foundation for future N-LDO designs, offering flexibility and adaptability for next-generation power management solutions. According to an embedment, the class AB amplifier configuration may provide precise control over sourcing and sinking currents, ensuring optimal performance for load conditions requiring bidirectional current handling.

The class AB amplifier designs with auxiliary loops for sinking capability often compromise load regulation, leading to performance degradation under varying load conditions. One or more embodiments of the disclosure may include a scheme that resolves limitations, offering superior regulation and stability.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable sub combination.

Moreover, although features may be described above as acting in certain combinations, one or more features from a combination can in some cases be excised from the combination, and the combination may be directed to a sub combination or variation of a sub combination.

What is claimed is:

1. A Low Dropout (LDO) regulator device comprising:
an amplifier configured to provide at least one of a linear output voltage and a feedback voltage, the linear output voltage indicating an error signal from a reference voltage;
a current mirror-based level shifter coupled with the amplifier, the current mirror-based level shifter configured to provide a stable reference current based on at least one of the linear output voltage and the feedback voltage; and
a power Metal Oxide Semiconductor Field Effect Transistor (MOSFET) module comprising a first N-channel MOSFET (NMOS) transistor configured to provide a sourcing power supply to a load and a second NMOS transistor configured to provide a sinking power supply to the load,
wherein the first NMOS transistor is coupled to the amplifier via the current mirror-based level shifter, and the second NMOS transistor is coupled to the amplifier.

2. The LDO regulator device as claimed in claim 1, wherein the amplifier comprises:
a source current compensation circuit configured to regulate sourcing current provided by the first NMOS transistor, and
a sink current compensation circuit configured to regulate sinking current absorbed by the second NMOS transistor to stabilize an output voltage.

3. The LDO regulator device as claimed in claim 1, wherein the amplifier comprises a biasing circuit configured to adjust a control voltage for the first NMOS transistor and the second NMOS transistor based on the linear output voltage.

4. The LDO regulator device as claimed in claim 3, wherein the biasing circuit is configured to decrease the linear output voltage of the amplifier and increase the control voltage of the first NMOS transistor to enable the sourcing power supply to the load based on a decreased linear output voltage.

5. The LDO regulator device as claimed in claim 3, wherein the biasing circuit is configured to increase the linear output voltage of the amplifier and increase the control voltage of the second NMOS transistor to enable the sinking power supply to the load based on an increased linear output voltage.

6. The LDO regulator device as claimed in claim 1, further comprises a super source follower circuit coupled with the amplifier via the current mirror-based level shifter and the first NMOS transistor,
wherein the super source follower circuit is configured to receive a level-shifted output signal from the current mirror-based level shifter and provide a low output impedance to drive a gate of the first NMOS transistor.

7. The LDO regulator device as claimed in claim 6, wherein the super source follower circuit comprises at least one PMOS transistor and at least one third NMOS transistor, wherein the third NMOS transistor is used as a common drain configuration and the at least one PMOS transistor is connected to an output node of the super source follower circuit to reduce an output impedance.

8. The LDO regulator device as claimed in claim 2, further comprises a source follower circuit coupled to the amplifier and the second NMOS transistor,
wherein the source follower circuit is configured to operate based on a voltage received from the sink current compensation circuit to buffer the linear output voltage of the amplifier, and provide a low output impedance to drive a gate of the second NMOS transistor.

9. The LDO regulator device as claimed in claim 8, wherein the source follower circuit is a common-drain amplifier, and
wherein the second NMOS transistor is connected to an output node of the source follower component.

10. The LDO regulator device as claimed in claim 1, further comprises a charge pump configured to generate a biasing voltage,
wherein the biasing voltage is applied to the first NMOS transistor.

11. The LDO regulator device as claimed in claim 1, wherein the amplifier comprises at least one PMOS transistor configured to act as a passive power transistor.

12. The LDO regulator device as claimed in claim 11, wherein the first NMOS transistor is biased based on a current across the at least one PMOS transistor.

13. The LDO regulator device as claimed in claim 1, wherein the amplifier is a class AB error amplifier.

14. A method for providing a sourcing power supply and a sinking power supply to a load, the method comprising:
generating, by an amplifier, at least one of a linear output voltage and a feedback voltage, the linear output voltage indicating an error signal derived from a reference voltage;
performing, by the amplifier, at least one of:
increasing a control voltage of a first NMOS device to enable the sourcing power supply to the load based on the linear output voltage;
increasing a control voltage of a second NMOS device to enable the sinking power supply to the load based on the linear output voltage; and
regulating an output voltage of a LDO regulator device to provide the sourcing power supply and the sinking power supply to the load.

15. The method as claimed in claim 14, further comprises generating a biasing voltage by a charge pump,
wherein the biasing voltage is applied to the first NMOS device.

16. The method as claimed in claim 14, wherein the amplifier comprises at least one PMOS transistor configured to act as a passive power transistor.

17. The method as claimed in claim 16, wherein the first NMOS device is biased based on a current across the at least one PMOS transistor.

18. The method as claimed in claim 14, wherein the amplifier is a class AB error amplifier.

19. A Low Dropout (LDO) regulator device comprising:
an amplifier configured to provide at least one of a linear output voltage and a feedback voltage, the linear output voltage indicating an error signal from a reference voltage;
a current mirror-based level shifter coupled with the amplifier, the current mirror-based level shifter configured to receive the at least one of the linear output voltage and the feedback voltage; and
a power Metal Oxide Semiconductor Field Effect Transistor (MOSFET) module comprising a first N-channel MOSFET (NMOS) transistor configured to provide a sourcing power supply to a load and a second NMOS transistor configured to provide a sinking power supply to the load,
wherein the current mirror-based level shifter includes:
a voltage-to-current converter configured to convert a voltage in a low voltage domain from the amplifier into a corresponding current signal;
a current mirror configured to change the corresponding current signal to a replicated current signal in a higher voltage domain; and
a current-to-voltage converter configured to convert the replicated current signal into a voltage in the higher voltage domain.

20. The LDO regulator device as claimed in claim 19, wherein the first NMOS transistor is coupled to the amplifier via the current mirror-based level shifter, and the second NMOS transistor is coupled to the amplifier.
